(19) United States
(12) Patent Application Publication
(10) Pub. No.: US 2024/0321617 A1
(43) Pub. Date: Sep. 26, 2024

(54) CLEAN ROOM

(71) Applicant: SHIN-ETSU HANDOTAI CO., LTD., Tokyo (JP)

(72) Inventor: Seiji SATOH, Annaka-shi (JP)

(73) Assignee: SHIN-ETSU HANDOTAI CO., LTD., Tokyo (JP)

(21) Appl. No.: 18/572,929

(22) PCT Filed: Jun. 20, 2022
(86) PCT No.: PCT/JP2022/024477

§ 371 Date: Dec. 21, 2023

(30) Foreign Application Priority Data
Jul. 27, 2021 (JP) 2021-122320

(51) Int. Cl. H01L 21/677; F24F 3/167; F24F 13/06

(52) U.S. Cl. CPC H01L 21/67769; F24F 3/167; F24F 13/06; H01L 21/6773

(57) ABSTRACT

The present invention is a clean room including a stocker area in which an article management storage is installed, in which the article management storage includes an upper opening part and a lower flow-out port configured to adjust the aperture ratio, a ceiling of the stocker area includes an eyelid and an air outlet port, the upper opening part of the article management storage and the air outlet port are connected to each other so as to be surrounded by the eyelid, and the clean room is configured that air supplied from the air outlet port is directly supplied into the article management storage through the upper opening part and is discharged from the lower flow-out port. This can provide the clean room that can keep the inside of the article management storage clean with almost no additional cost and without reducing the storing volume in the article management storage.

### TECHNICAL FIELD

The present invention relates to a clean room and an article management storage (stocker) installation for storing (managing), such as a wafer storage container: FOUP or FOSB within the clean room in a semiconductor manufacturing factory.

### BACKGROUND ART

In a factory for manufacturing a semiconductor, such as a product yield of a step of producing a semiconductor wafer is lowered due to contamination of a clean room from an environment, thus the wafer is produced in the clean room where temperature and humidity are controlled, and an extraneous substance (particles) of several microns level are removed. An air introduced by an outdoor air system, in which temperature and humidity are controlled, is provided through a ULTRA Low Penetration Air (ULPA) filter to remove the particles, and then to a work area in the clean room. When more strict control of cleanness in the work area is necessitated, the air with higher cleanness, in which chemical contaminants has been removed with an additional chemical filter, can be provided to the work area.

On the other hand, in a semiconductor manufacturing step, the wafer is transported in the state of being housed in a sealed container, i.e., Front Opening Unified Pod (FOUP), and stored. Many products go back and forth on manufacturing steps within the clean room. Before and after being mounted and processed on a manufacturing apparatus or an inspection apparatus, the product is housed on a shelf in the article management storage (stocker) where these FOUPs are stored. In the article management storage, a number assigned to manage the wafer housed in the FOUP is linked with a management number of the FOUP and further linked with the location information of the shelf in the article management storage. The FOUP to be processed at the manufacturing apparatus or the inspection apparatus is stored and taken out from the article management storage based on this management information.

Patent document 1 discloses a method for storing a wafer in a cassette in an airtight container to prevent the formation of a native oxide film on the wafers and the absorption of chemical substances in an article storage where the wafer cassette is stored in a clean room.

Patent document 2 discloses a clean room having a clean room air conditioning method in which an air circulation flow different from the clean room air circulation flow is supplied directly to the vicinity of the interface box opener on which the wafer storage box is mounted.

Patent document 3 discloses a contaminated airflow, which is generated by an article-transport vehicle while moving in an article storage for a clean room, is controlled using an air-flow controlling plate installed on the article-transport vehicle. Thus, the airflow does not flow back toward the article-storing side.

Patent document 4 discloses a clean room installation in which a high cleanness region and a low cleanness region are partitioned by an eyelid (hanging wall), an underfloor area is further divided, and the pressure is increased in the order of the higher cleanness in the clean room.

Patent Document 5 discloses a clean room with an eyelid (hanging wall) between the clean room and a return room.

### CITATION LIST

### Patent Literature

Patent Document 1: JP H05-201506 A
Patent Document 2: JP 2001-093790 A
Patent Document 3: JP 2007-269489 A
Patent Document 4: JP 2002-005485 A
Patent Document 5: JP 2008-157474 A

### SUMMARY OF INVENTION

### Technical Problem

When the FOUP is stored and taken out, a transport vehicle moves to the front of a required FOUP. The transfer robot moves up and down along a column attached to the vehicle, and then the robot stabilizes at the height of the shelf on which the required FOUP is mounted, and the FOUP is transferred from the shelf to the transfer robot. Then, the transport vehicle and the transfer robot move to a FOUP gateway and can carry the FOUP out from the FOUP gateway.

The transport vehicle and the transfer robot in the article management storage have a mechanical driving part, thus, the mechanical portion becomes a source of dust generation whenever the mechanical portion operates. Consequently, a degrading of the cleanness in the article management storage or the clean room has been a problem. Though installing an additional filter or a blower fan within the article management storage is possible, increased cost for installation or decreased storing volume of the article management storage due to the filter or the blower fan is problematic. Moreover, depending on the configuration of the blower fan in the article management storage, contaminated air with generated dust from the transport vehicle and the transfer robot may flow out from the FOUP gateway, thus matching air-blow and air pressure condition in the clean room with air blow and air pressure condition in the article management storage has been difficult, and problematic.

The present invention has been made to solve the above-described problem. An object of the present invention is to provide a clean room that can keep the inside of an article management storage clean without generating an additional cost or reducing a storing volume of the article management storage.

### Solution to Problem

To solve the above-described problem, the present invention provides a clean room comprising:
a stocker area in which an article management storage is installed, wherein
the article management storage includes an upper opening part and a lower flow-out port configured to adjust aperture ratio,
a ceiling of the stocker area includes an eyelid and an air outlet port,
the upper opening part of the article management storage and the air outlet port are connected to each other so as to be surrounded by the eyelid, and
the clean room is configured that air supplied from the air outlet port is directly supplied into the article management storage through the upper opening part and is discharged from the lower flow-out port.

According to the inventive clean room, the upper opening part of the article management storage and the air outlet port on the ceiling of the stocker area are surrounded by the eyelid (hanging wall), and clean air from a part of the clean room ceiling surrounded by the eyelid directly flows into the article management storage. Consequently, clean air becomes a laminar flow in an unchanged state and can discharge contaminated air due to dust generation from, for example, a transfer robot or a transport vehicle in the article management storage from the lower flow-out port of the article management storage.

Moreover, the inventive clean room can utilize a part of the air outlet port of the clean room ceiling; thus, supplementing an additional cleaning system in the stocker area is unnecessary. Furthermore, the eyelid is configured to surround the upper opening part of the article management storage, thus reducing the storing volume of the article management storage is unneeded.

Thus, according to the inventive clean room, the cleanness in the article management storage can be kept without generating an additional cost or reducing the storing volume of the article management storage.

An article to be managed by the article management storage may be FOUP or FOSB.

The article to be managed by the article management storage is not particularly limited but can be such as FOUP or FOSB.

### Advantageous Effects of Invention

As described above, the inventive clean room can keep the inside of an article management storage clean without generating additional costs or reducing the storing volume of the article management storage.

### BRIEF DESCRIPTION OF DRAWINGS

FIG. 1 is a view illustrating a schematic view of an example of a clean room according to the present invention.

FIG. 2 is a view illustrating a schematic view of the clean room illustrated in FIG. 1 observed from a different diction.

FIG. 3 is a view illustrating a schematic view of a clean room in Comparative Example.

FIG. 4 is a view illustrating a schematic view of the clean room illustrated in FIG. 3 observed from a different direction.

FIG. 5 is a graph showing the numbers of airborne particles in Example and Comparative Example.

### DESCRIPTION OF EMBODIMENTS

As described above, it is desired to be able to discharge contaminated air due to dust generated from a transport vehicle or a transfer robot in an article management storage where FOUP is housed and stored therein in a clean room so as not to leak into a work area.

To solve the above problem, the present inventors have earnestly studied and found out that by surrounding an upper opening part of the article management storage, and an air outlet port configured in the stocker area among the air outlet ports in the ceiling of the clean room with an eyelid (hanging wall), contaminated air can be discharged from a stocker area in a simple manner without leaking into the work area, in which the air is contaminated by dust generated from a transport vehicle or a transfer robot in the article management storage concerning the article management storage where houses and stores the FOUP in the clean room. Based on this finding, the present invention has been completed.

For example, from the viewpoint of cost, a material for the eyelid can be made of a metal frame, such as aluminum, surrounded by a resin plate or sheet, such as vinyl chloride or polycarbonate. In addition, using a resin with an antistatic effect is preferable to prevent particles from adhering.

That is, the present invention is a clean room comprising:

a stocker area in which an article management storage is installed, wherein
the article management storage includes an upper opening part and a lower flow-out port configured to adjust aperture ratio,
a ceiling of the stocker area includes an eyelid and an air outlet port,
the upper opening part of the article management storage and the air outlet port are connected to each other so as to be surrounded by the eyelid, and
the clean room is configured that air supplied from the air outlet port is directly supplied into the article management storage through the upper opening part and is discharged from the lower flow-out port.

Hereinafter, the present invention will be described in detail with reference to the drawings. However, the present invention is not limited thereto.

### EMBODIMENT

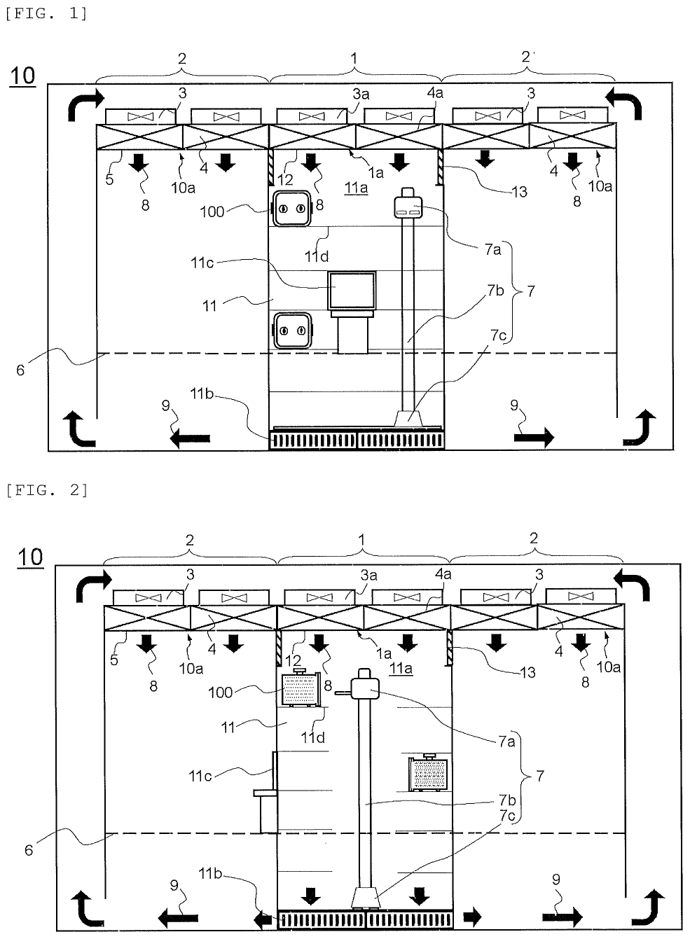

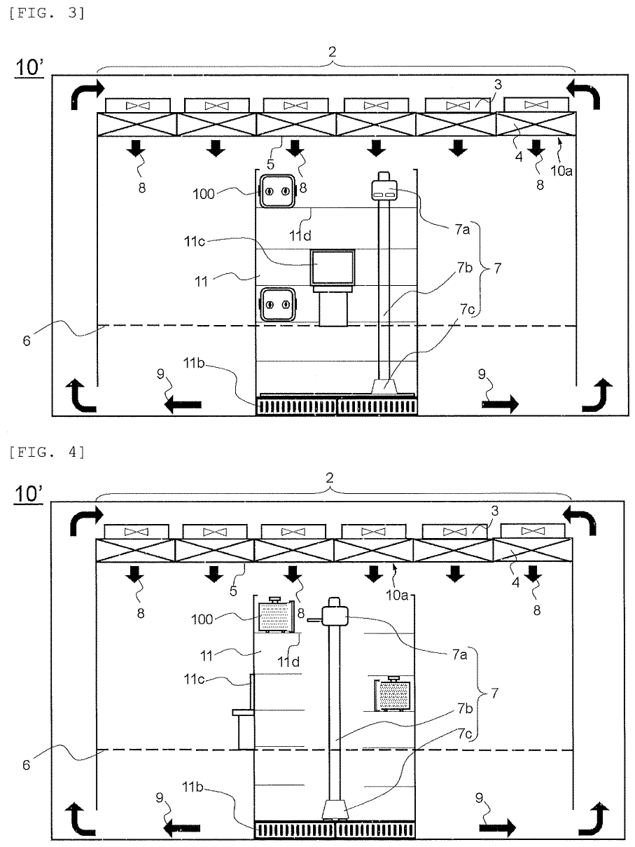

In the following, with reference to FIG. 1 and FIG. 2, the clean room which is one embodiment according to the present invention, and the article management storage (stocker), in which FOUP is stored and housed, in the clean room are described.

FIG. 1 is a schematic diagram of an example of an inventive clean room and an example of an article management storage that houses and stores FOUP in the clean room. FIG. 2 is a schematic diagram of the clean room and the article management storage illustrated in FIG. 1, rotated by 90 degrees from the viewpoint of FIG. 1.

Overall, FIG. 1 and FIG. 2 illustrate a simple discharge method for contaminated air to prevent leaking into the work area concerning the article management storage (stocker) that stores and houses FOUP in one example of the inventive clean room, in which the air is contaminated by the dust generated from the transport vehicle or the transfer robot in the article management storage installed in the stocker area.

A clean room 10, shown in FIG. 1 and FIG. 2, includes a stocker area 1. The clean room 10 further includes a work area 2 adjacent to the stocker area 1. The clean room 10, shown in FIG. 1 and FIG. 2, is clearly partitioned into the stocker area 1 and the work area 2 by a side surface of an article management storage 11 and an eyelid 13, as described below.

Lower portions of the stocker area 1 and the work area 2 of the clean room 10 are partitioned from the other portion by a grating 6.

A plurality of blower fan 3 are installed on a ceiling 10a of the clean room 10. For example, the blower fan 3 can supply air with controlled temperature and humidity.

A ULPA filter 4 is provided at an air outlet of each blower fan 3. The ULPA filter 4 can remove an extraneous substance (particles) at the micron level from the air supplied by the blower fan 3 and supply clean air 8 into the clean room 10 from an air outlet port 5 on the side opposite to the blower fan 3.

The article management storage 11 (stocker) is installed in the stocker area 1.

The article management storage 11 is provided with an upper opening part 11a, and a lower flow-out port 11b configured to adjust aperture ratio. In addition, the article management storage 11 further includes a FOUP gateway 11c, which is an opening on a side portion.

The article management storage 11 is provided with a plurality of shelves 11d and is configured to mount FOUP 100 for managing and housing FOUP 100 on the shelves 11d.

A transport apparatus 7 is stored in the article management storage 11. The transport apparatus 7 includes a transport vehicle 7c, a transport column 7b supported by the transport vehicle 7c, and a transfer robot 7a capable of ascending and descending along the transport column 7b. The transport apparatus 7 is configured to be capable of self-propelling by the transport vehicle 7c and adjusting the height of the transfer robot 7a to the height of a target shelf 11d and to the height of the FOUP gateway 11c. The transfer robot 7a is configured to be able to deliver and receive the FOUP 100 on the shelf 11d or at the FOUP gateway 11c.

Moreover, a ceiling 1a of the stocker area 1 includes the eyelid 13 (hanging wall) and an air outlet port 12.

The air outlet port 12 is an air outlet port of the ULPA filter 4a provided to the blower fan 3a installed on the ceiling 1a of the stocker area 1 among the ULPA filters 4 installed on the ceiling 10a of the clean room 10.

Although FIG. 1 and FIG. 2 illustrate a cross-sectional view, the eyelid 13 surrounds the upper opening part 11a of the article management storage 11 and the air outlet port 12. The upper opening part 11a of the article management storage 11 and the air outlet port 12 are connected to each other so as to be surrounded by the eyelid 13.

As shown in FIG. 1 and FIG. 2, in the article management storage 11 for storing and housing the FOUP 100 in the clean room 10, the upper opening part 11a of the article management storage 11 is connected to the outlet port 12 (the air outlet port) for the clean air 8 on the ceiling 1a of the stocker area 1 by the eyelid 13 (the hanging wall). The clean air 8 supplied from the air outlet port 12 on the ceiling 1a of the stocker area 1, in which the air outlet port 12 is located above the article management storage 11, is directly taken into the article management storage 11. As a result, the air flows as a laminar flow from the upper opening part 11a to the lower flow-out port 11b of the article management storage 11.

Even if the transport vehicle 7c or the transfer robot 7a are driven in the article management storage 11, and dust is generated from these driving portions and then the air is contaminated, the possibility that the contaminated air comes into contact with the FOUP 100 housed on the shelf 11d (storage portion) of the article management storage 11 is reduced. This is because the air flows in a laminar manner from the upper opening part 11a of the article management storage 11 to the lower flow-out port 11b. Moreover, an aperture ratio of the lower flow-out port 11b of the article management storage 11 can be adjusted so to prevent the contaminated air from blowing out from the FOUP gateway 11c, which is another opening, to the work area 2, thus discharging the contaminated air from the lower flow-out port 11b in the lower portion of the article management storage 11. The aperture ratio of the lower flow-out port 11b depends on the area of the upper opening part 11a of the article management storage 11, the area and blowout volume of the air outlet port 12 on the ceiling 1a of the stocker area 1 of the clean room 10 surrounded by the eyelid 13 above the upper opening part 11a. The ratio can be adjusted accordingly to prevent air from blowing out from the FOUP gateway 11c. The flow-out balance between the lower flow-out port 11b and the FOUP gateway 11c can be adjusted by adjusting the aperture ratio of the lower flow-out port 11b of the article management storage 11 so as to prevent the contaminated air from discharging from the FOUP gateway 11c and can be adjusted without being affected by air pressure or airflow conditions of the clean room.

As shown in FIG. 1 and FIG. 2, an air 9 that passes through the article management storage 11 and is discharged from the lower flow-out port 11b of the article management storage 11, then passes through the lower side of the work area 2 and further then the side of the work area 2 and is circulated to the blower fan 3 and 3a without coming into the work area 2. Particles such as dust contained in the air 9 are removed by the ULPA 4 and 4a.

In this way, in an example of the inventive clean room, the air supplied from the air outlet port of the clean air on the ceiling located on the upper portion of the article management storage is directly taken into the article management storage by virtue of the eyelid (hanging wall), the contaminated air is discharged from the lower part of the article management storage by adjusting the aperture ratio of the lower flow-out port of the article management storage so as to prevent the air from blowing out from the FOUP gateway, being the opening.

Should be noted that, in the above description, an example in which an object managed by the article management storage 11 is a FOUP 100 has been described, however, the object managed by the article management storage 11 is not limited to the FOUP. For example, the article management storage 11 may manage a FOSB (front shipping box) used when a semiconductor wafer as a material is shipped and transported from a semiconductor material manufacturer to a semiconductor device manufacturer.

### EXAMPLE

Hereinafter, the present invention will be specifically described with reference to Example and Comparative Example. However, the present invention is not limited thereto.

### EXAMPLE

In Example, FOUP 100 was managed and housed in an article management storage 11 in the clean room 10 shown in FIG. 1 and FIG. 2.

### COMPARATIVE EXAMPLE

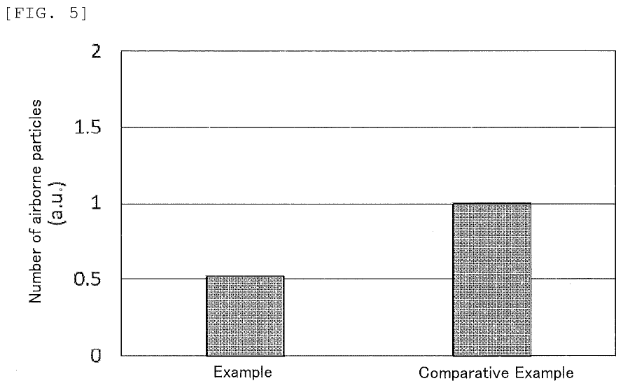

In Comparative Example, FOP 100 was managed and housed in an article management storage 11 in a clean room 10′ shown in FIG. 3 and FIG. 4.

FIG. 3 is a schematic diagram of an example of a clean room and the article management storage that stored and housed the FOUP in the clean room according to Comparative Example. FIG. 4 is a schematic diagram of the clean room and the article management storage shown in FIG. 3, rotated by 90 degrees from the viewpoint of FIG. 1.

The clean room 10′ shown in FIG. 3 and FIG. 4 were greatly different from the clean room 10 shown in FIG. 1 and FIG. 2 in that an eyelid was not provided on a ceiling 10a.

In the clean room 10′, because no eyelid was shown in FIG. 1 and FIG. 2, an area where the article management storage 11 was installed and a work area 2 were not clearly partitioned from each other. This means that the article management storage 1 was installed in the work area 2 in the clean room 10.

### (Result)

The number of airborne particles of 0.1 μm or more in the air discharged from a lower flow-out port 11b of the article management storage 1 was measured 10 times by an Airborne Particle Counter KC-24 manufactured by RION Co., Ltd., and after calculating the mean value thereof, the mean value was normalized and compared between Example and Comparative Example. FIG. 5 shows the number of airborne particles in Example and Comparative Example when the number of particles in Comparative Example is defined as 1.

As shown in FIG. 5, when the mean value of the number of airborne particles in Comparative Example was defined as 1, the mean value of the number of airborne particles in Example was 0.52. In other words, the inside of the article management storage 11 in Example was able to be kept cleaner than in Comparative Example.

On the other hand, in the clean room 10′ in Comparative example, dust accumulated in the article management storage 11, and these needed to be cleaned periodically (every about one to two years), and an operation of the article management storage 11 required to be suspended at this time. In addition, due to the accumulation of the dust, for example, the dust adhered to the outside of the FOUP 100, and when the cover of the FOUP was opened, the risk of dust contamination of wafers increased, and the risk of dust contamination of the entire clean room 10′ from the article management storage 11 through the opening such as a FOUP gateway 11c also increased.

In addition, managing and housing were performed in the same manner as in Example above, except that the FOUP managed in the article management storage 11 was changed to a FOSB. As a result, even when the FOSB was managed, the inside of the article management storage 11 was able to be kept clean by using the inventive clean room.

Furthermore, in the clean room 10 in Example, such as a blower fan or a ULPA filter was not added to the clean room 10′ in Comparative Example, and the storage volume of the article management storage 11 was not reduced.

These facts indicate that the inventive clean room can keep the inside of the article management storage clean with almost no additional cost and without reducing the storing volume in the article management storage.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A clean room comprising:
a stocker area in which an article management storage is installed, wherein
the article management storage includes an upper opening part and a lower flow-out port configured to adjust aperture ratio,
a ceiling of the stocker area includes an eyelid and an air outlet port,
the upper opening part of the article management storage and the air outlet port are connected to each other so as to be surrounded by the eyelid, and
the clean room is configured that air supplied from the air outlet port is directly supplied into the article management storage through the upper opening part and is discharged from the lower flow-out port.

2. The clean room according to claim 1, wherein
an article to be managed by the article management storage is FOUP or FOSB.
